(19) United States
(12) Patent Application Publication
(10) Pub. No.: US 2025/0014924 A1
(43) Pub. Date: Jan. 9, 2025

(54) SUBSTRATE PROCESSING APPARATUS, SUBSTRATE PROCESSING SYSTEM, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Tsukasa KAMAKURA, Toyama (JP)

(21) Appl. No.: 18/755,943

(22) Filed: Jun. 27, 2024

(30) Foreign Application Priority Data
Jul. 3, 2023 (JP) 2023-109674

(51) Int. Cl. H01L 21/67; H01L 21/677; H01L 21/687

(52) U.S. Cl. CPC H01L 21/67253; H01L 21/67161; H01L 21/67184; H01L 21/6773; H01L 21/68707

(57) ABSTRACT

To reduce a burden on an operating personnel in setting transfer operation information of a transfer robot configured to transfer a substrate, there is provided a technique that includes: a placement chamber for placing a container accommodating a substrate; a first transfer chamber including a first transfer robot; process modules for processing the substrate; a second transfer chamber including a second transfer robot; a memory storing a plurality of pieces of layout information indicating arrangements of the placement chamber, the first transfer chamber, the second transfer chamber and the process modules; and a controller for controlling operations of the first transfer robot and the second transfer robot based on at least one of the plurality of pieces of layout information in the memory.

### CROSS REFERENCE TO RELATED APPLICATIONS

This non-provisional U.S. patent application is based on and claims priority under 35 U.S.C. § 119 to Japanese Patent Application No. 2023-109674 filed on Jul. 3, 2023, in the Japanese Patent Office, the entire contents of which are hereby incorporated by reference.

### TECHNICAL FIELD

The present disclosure relates to a substrate processing apparatus, a substrate processing system, a method of manufacturing a semiconductor device and a non-transitory computer-readable recording medium.

### BACKGROUND

According to some related arts, a technique capable of controlling an extension/retraction and a rotational speed of a substrate transfer robot in a semiconductor manufacturing apparatus such as a substrate processing apparatus is disclosed.

For example, when the substrate processing apparatus is installed in a site such as a factory, an operating personnel performs a setting operation of setting transfer operation information of a transfer robot configured to transfer a substrate in accordance with an arrangement of each chamber constituting the substrate processing apparatus.

### SUMMARY

According to the present disclosure, there is provided a technique capable of reducing a burden on an operating personnel in setting transfer operation information of a transfer robot configured to transfer a substrate.

According to an aspect of the present disclosure, there is provided a technique that includes: a placement chamber in which a container accommodating a substrate is placed; a first transfer chamber provided with a first transfer robot therein, wherein the first transfer robot is configured to transfer the substrate to and from the container; a plurality of process modules configured to process the substrate; a second transfer chamber provided with a second transfer robot therein and configured to transfer and deliver the substrate between the first transfer chamber and each of the plurality of process modules; a memory configured to store a plurality of pieces of layout information indicating arrangements of the placement chamber, the first transfer chamber, the second transfer chamber and the plurality of process modules; and a controller configured to be capable of controlling operations of the first transfer robot and the second transfer robot based on at least one of the plurality of pieces of layout information in the memory, wherein the plurality of pieces of layout information are different from each other in the arrangements of at least one of the placement chamber, the first transfer chamber, the second transfer chamber and the plurality of the process modules.

### BRIEF DESCRIPTION OF THE DRAWINGS

FIG. 1 is a diagram schematically illustrating a substrate processing apparatus according to one or more embodiments of the present disclosure, when viewed from above.

FIG. 2A is a diagram schematically illustrating the substrate processing apparatus according to the embodiments of the present disclosure, when viewed from a side thereof.

FIG. 2B is a diagram schematically illustrating a cross-section of a process module included in the substrate processing apparatus according to the embodiments of the present disclosure.

FIG. 3 is a block diagram schematically illustrating a configuration of a controller and related components of the substrate processing apparatus according to the embodiments of the present disclosure.

FIG. 4 is a diagram schematically illustrating a setting screen for setting an apparatus configuration of the substrate processing apparatus according to the embodiments of the present disclosure.

FIG. 5 is a diagram schematically illustrating the apparatus configuration which is set according to the embodiments of the present disclosure.

FIG. 6 is a diagram schematically illustrating layout information of the apparatus configuration of the substrate processing apparatus according to the embodiments of the present disclosure.

FIG. 7 is a diagram schematically illustrating a setting flow for the layout information in the substrate processing apparatus according to the embodiments of the present disclosure.

FIG. 8 is a diagram an arrangement of a plurality of substrate processing apparatuses included in a substrate processing system according to the embodiments of the present disclosure.

### DETAILED DESCRIPTION

### Embodiments of Present Disclosure

Hereinafter, one or more embodiments (also simply referred to as “embodiments”) of the technique of the present disclosure will be described in detail with reference to the drawings. Further, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### <Substrate Processing Apparatus>

A substrate processing apparatus 20 according to the present embodiments is configured as a substrate processing apparatus provided with a vertical type reaction furnace (process furnace).

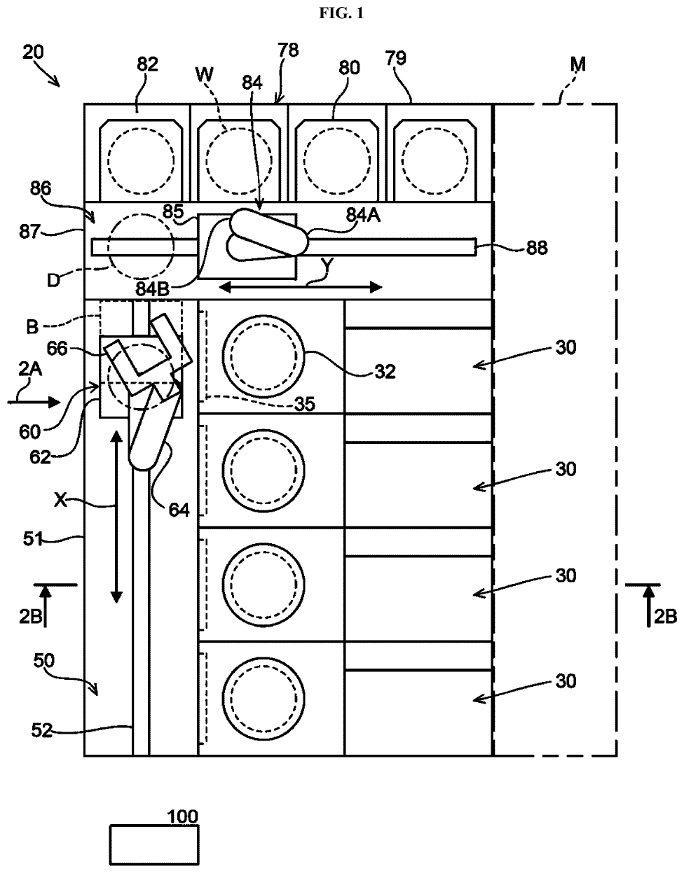

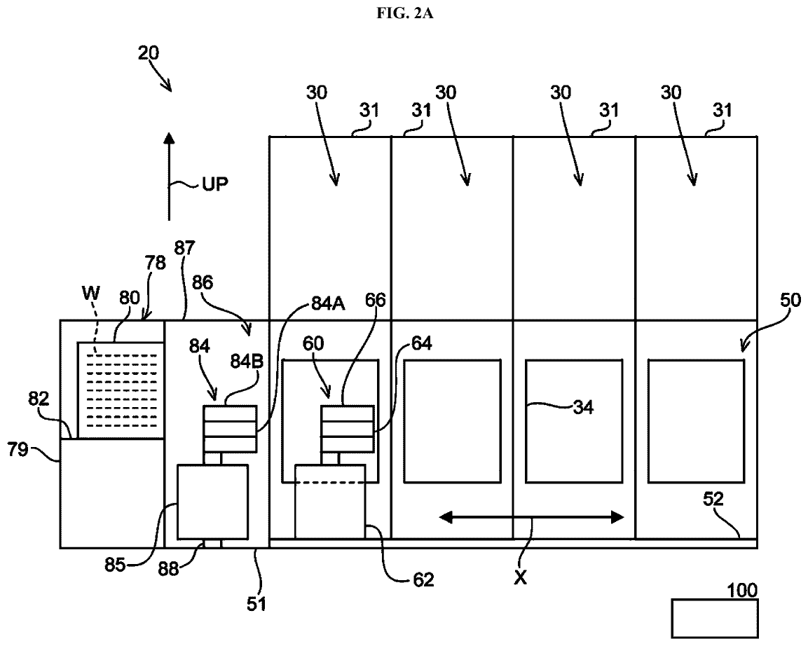

As shown in FIGS. 1, 2A and 2B, the substrate processing apparatus 20 includes a plurality of process modules 30 configured to process a substrate (wafer) W. For example, according to the present embodiments, the substrate processing apparatus 20 includes four process modules 30. However, the present embodiments are not limited thereto. For example, the number of process modules 30 included in the substrate processing apparatus 20 may be three or less or five or more. Hereinafter, each of the process modules 30 may also be referred to as a “process module 30”.

As shown in FIG. 1, the four process modules 30 are arranged in a row in a horizontal direction. The four process modules 30 are capable of independently processing the substrate W. That is, the four process modules 30 are independently controlled by a controller 100 described later.

For example, the substrate W described herein may include objects such as a product substrate, a dummy substrate and a monitor substrate. That is, the substrate W supported by a substrate support 40 may be the product substrate, the dummy substrate or the monitor substrate. Further, the substrate support 40 may support a plurality of substrates including the substrate W. Hereinafter, the plurality of substrates including the substrate W may also be referred to as “substrates W”. In such a case, the substrate support 40 may support the substrates W such as product substrates, dummy substrates, monitor substrates and a combination thereof.

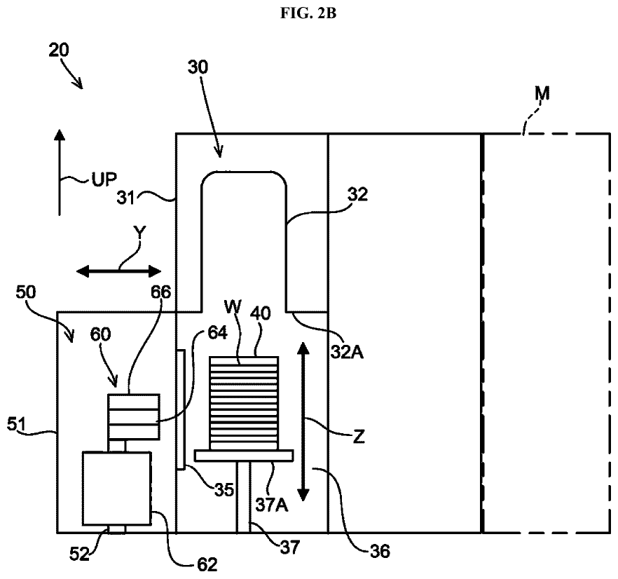

As shown in FIG. 2B, the process module 30 may include a reaction furnace (also referred to as a “reactor”) 32 serving as an example of a process vessel. The reaction furnace tor 32 is provided at an upper portion of the process module 30. The substrate W is charged (loaded) inside the reaction furnace 32. Specifically, the substrate support 40 configured to support at least one substrate W is loaded (transferred) into the reaction furnace 32. Further, a space inside the reaction furnace 32 may also be referred to as a “process chamber” in which the substrate W is processed. A gas supplier (which is a gas supply structure or a gas supply system) (not shown) configured to supply a gas such as a process gas and an inert gas into the reaction furnace 32 is connected to the reaction furnace 32. A predetermined amount of the gas is supplied into the reaction furnace 32 through the gas supplier. Further, an exhauster (which is an exhaust structure or an exhaust system) (not shown) configured to exhaust a substance such as the process gas and the inert gas from the reaction furnace 32 is connected to the reaction furnace 32. An inner pressure of the reaction furnace 32 is regulated (controlled or adjusted) by the exhauster. Further, a heater (not shown) serving as an example of a heating structure is arranged around an outer periphery of the reaction furnace 32. An inner temperature of the reaction furnace 32 is regulated by the heater. According to the present embodiments, as shown in FIG. 3, the gas supplier, the exhauster and the heater provided in the process module 30 are controlled by a temperature controller 122, a gas flow rate controller 124 and a pressure controller 126, respectively. In addition, the temperature controller 122, the gas flow rate controller 124 and the pressure controller 126 are controlled by the controller 100 described later.

The substrate W loaded into the reaction furnace 32 is heated by the heater in the reaction furnace 32 and is processed by the process gas supplied through the gas supplier. In such a manner, the substrate W is processed in the reaction furnace 32, that is, in the process chamber so as to form a film thereon.

The process module 30 further includes a preparation chamber 36. The preparation chamber 36 is provided at a lower portion of the process module 30. In other words, the preparation chamber 36 is located below the reaction furnace 32. The preparation chamber 36 communicates with an inside of the reaction furnace 32, that is, with the process chamber, through a furnace opening 32A of the reaction furnace 32. An elevator (which is an elevating structure) 37 to which the substrate support 40 is fixed is provided at the preparation chamber 36. The elevator 37 is configured to move the substrate support 40 fixed to an elevating table 37A upward together with the elevating table 37A, and thereby, loads (inserts) the substrate support 40 into the reaction furnace 32. A periphery of the elevating table 37A contacts a periphery of the furnace opening 32A of the reaction furnace 32 via a seal (not shown) to separate the inside of the reaction furnace 32 and an inside of the preparation chamber 36. In addition, the elevator 37 is provided with a function of rotating the elevating table 37A in the horizontal direction with a vertical direction as an axis. In FIG. 2B, an arrow “Z” indicates an elevating direction in which the elevating table 37A is elevated and lowered by the elevator 37. The elevating direction of the elevating table 37A in the present embodiments is the same as the vertical direction.

The process module 30 further includes an entrance 34 through which the substrate W is loaded into and unloaded out of the process module 30. The entrance 34 is opened and closed by a gate valve 35. A plurality of entrances including the entrance 34 are provided for the process modules 30, respectively. Hereinafter, the plurality of entrances including the entrance 34 may also be referred to as “entrances 34”. Further, a size of the entrance 34 according to the present embodiments is such that the substrate W and a telescopic arm 64 and a hand portion 66 of a second transfer robot 60 supporting the substrate W are capable of being loaded into and unloaded out of the process module 30.

### <Second Transfer Chamber>

As shown in FIGS. 1 and 2B, the substrate processing apparatus 20 includes a second transfer chamber 50 provided with the second transfer robot 60 therein. The second transfer chamber 50 extends in a direction in which the four process modules 30 are arranged. Further, the second transfer chamber 50 is provided adjacent to each process module 30 and a first transfer chamber 86. The second transfer chamber 50 communicates with each process module 30 via the entrance 34 of each process module 30. A housing 51 constituting the second transfer chamber 50 is fixed to a housing 31 constituting the process module 30. An inside of the second transfer chamber 50 is maintained at a cleanliness level suitable for transferring the substrate W in an atmospheric atmosphere. However, the present embodiments are not limited thereto. For example, an apparatus such as an exhauster (which is an exhaust structure or an exhaust system) may be connected to the second transfer chamber 50 to create a vacuum atmosphere inside the second transfer chamber 50 to maintain the cleanliness level suitable for transferring the substrate W.

A transfer rail 52 is provided on a floor of the second transfer chamber 50, and extends in the direction in which the four process modules 30 are arranged. The second transfer robot 60 moves along the transfer rail 52. More specifically, the second transfer robot 60 transfers the substrate W along the transfer rail 52 while holding (supporting or accommodating) the substrate W. Hereinafter, a direction in which the second transfer robot 60 moves, that is, a direction in which the substrate W is transferred, may be appropriately referred to as a “substrate transfer direction”. The substrate transfer direction is a direction indicated by an arrow “X” in FIG. 1. Further, a direction indicated by an arrow “UP” in FIGS. 2A and 2B is an upward direction in the vertical direction.

### <Second Transfer Robot>

As shown in FIG. 1, the second transfer robot 60 is configured to move within the second transfer chamber 50 along the transfer rail 52. Further, the second transfer robot 60 is a structure capable of moving while holding the substrate W. The second transfer robot 60 is controlled by the controller 100 such that the second transfer robot 60 moves between a target process module (that is, a designated process module) among the process modules 30 and a substrate delivery position D. Further, the substrate delivery position D refers to a position where the substrate W is transferred and delivered between a first transfer robot 84 and the second transfer robot 60, and refers to a position indicated by a two-dot chain line in FIG. 1. The substrate delivery position D shown in FIG. 1 is an example, and it is preferable to set an optimal position depending on respective configurations and apparatus conditions of the first transfer robot 84 and the second transfer robot 60.

The second transfer robot 60 is configured to be capable of transferring and delivering the substrate W between the first transfer chamber 86 and the process module 30. Specifically, as shown in FIGS. 1 and 2A, the second transfer robot 60 includes a transfer table 62, the telescopic arm 64 and the hand portion 66.

The transfer table 62 is a pedestal that moves on the transfer rail 52. A driving structure (not shown) is provided inside the transfer table 62 such that the transfer table 62 is moved in a transfer direction along the transfer rail 52.

The telescopic arm 64 is provided on the transfer table 62 so as to be rotatable in the horizontal direction. The telescopic arm 64 is configured to be extendable and retractable.

The hand portion 66 is provided at a front end (tip) of the telescopic arm 64. The hand portion 66 is configured to hold the substrate W. Specifically, the hand portion 66 is configured to hold the substrate W by supporting the substrate W from thereunder.

The second transfer robot 60 further includes an elevator (which is an elevating structure) (not shown) capable of elevating and lowering the telescopic arm 64 with respect to the transfer table 62. The telescopic arm 64 is moved up and down with respect to the transfer table 62 by the elevator of the second transfer robot 60.

By extending and retracting the telescopic arm 64 with respect to the substrate support 40, the second transfer robot 60 is configured to be capable of transferring the substrate W held by the hand portion 66 to the substrate support 40 and capable of receiving the substrate W (which is processed) from the substrate support 40.

An operation of the second transfer robot 60 to transfer and deliver the substrate W to and from the substrate support 40 and an operation of the second transfer robot 60 to transfer and deliver the substrate W to and from the first transfer robot 84 are controlled by a transfer controller 110. Specifically, in the second transfer robot 60, a movement operation of the transfer table 62, an extension and retraction operation of the telescopic arm 64 and an elevating and lowering operation of the telescopic arm 64 are controlled by the transfer controller 110. Further, the controller 100 determines which one of the four process modules 30 is to be selected as a destination to and from which the second transfer robot 60 transfers and delivers the substrate W.

### <Placement Chamber>

As shown in FIG. 1, the substrate processing apparatus 20 includes a placement chamber (also referred to as a “mounting table”) 78 provided with a loading port structure 82 on which a container 80 is placed.

The container 80 may refer to a container capable of accommodating at least one substrate W and capable of being delivered externally. For example, a FOUP (Front Opening Unified Pod) may be used as the container 80. However, the container 80 is not limited thereto. Further, a plurality of containers including the container 80 may be provided. Hereinafter, the plurality of containers including the container 80 may also be referred to as “containers 80”. Further, in each container 80, as the substrate W, the object such as the product substrate, the dummy substrate and the monitor substrate is accommodated.

The loading port structure 82 is a pedestal on which the container 80 is capable of being placed. As an example, according to the present embodiments, a plurality of loading port structures (for example, four loading port structures) including the loading port structure 82 are arranged in a line in a direction perpendicular to the substrate transfer direction when viewed from above of the substrate processing apparatus 20. However, the present embodiments are not limited thereto. Hereinafter, the plurality of loading port structures including loading port structure 82 may also be referred to as “loading port structures 82”. For example, the number of the loading port structures 82 may be more than four or less than four.

The container 80 and the loading port structure 82 are arranged in the placement chamber 78. The placement chamber 78 is constituted by a housing 79.

### <First Transfer Chamber>

As shown in FIG. 1, the substrate processing apparatus 20 includes the first transfer chamber 86 provided with the first transfer robot 84 therein. The first transfer chamber 86 extends in the direction perpendicular to the substrate transfer direction when viewed from above. Further, the direction perpendicular to the substrate transfer direction may also be appropriately referred to as a “substrate delivery direction”. In FIG. 1, the substrate delivery direction is indicated by an arrow “Y”.

The first transfer chamber 86 is provided between the placement chamber 78 and the process module 30. A first side surface of a housing 87 constituting the first transfer chamber 86 is connected to the housing 31 of the process module 30. At a second side surface of the housing 87 opposite to the first side surface thereof, entrances (not shown) through which the substrate W is transferred are provided at positions corresponding to the four loading port structures 82, respectively. The entrances are opened and closed by shutters (not shown), respectively. An inside of the first transfer chamber 86 is maintained at a cleanliness level suitable for transferring the substrate W in the atmospheric atmosphere. However, the present embodiments are not limited thereto. For example, an apparatus such as an exhauster (which is an exhaust structure or an exhaust system) may be connected to the first transfer chamber 86 to create the vacuum atmosphere inside the first transfer chamber 86 to maintain the cleanliness level suitable for transferring the substrate W.

### <First Transfer Robot>

As shown in FIG. 1, the first transfer robot 84 is configured to move within the first transfer chamber 86 along a rail 88. Further, the first transfer robot 84 is a structure capable of moving while holding the substrate W. The first transfer robot 84 is controlled by the controller 100 such that the first transfer robot 84 moves between a target container (that is, a designated container) among the containers 80 and the substrate delivery position D.

The first transfer robot 84 is configured to be capable of transferring the substrate W to and from the container 80 placed on the loading port structure 82. Further, the first transfer robot 84 is configured to be capable of directly transferring and delivering the substrate W to and from the second transfer robot 60. Specifically, as shown in FIGS. 1 and 2A, the first transfer robot 84 includes a moving table 85, a telescopic arm 84A and a hand portion 84B.

The moving table 85 is a pedestal that moves on the rail 88. A driver (which is a driving structure) (not shown) is provided inside the moving table 85 such that the moving table 85 is moved in the substrate delivery direction along the rail 88.

The telescopic arm 84A is provided on the moving table 85 so as to be rotatable in the horizontal direction. The telescopic arm 84A is configured to be extendable and retractable.

The hand portion 84B is provided at a front end (tip) of the telescopic arm 84A. The hand portion 84B is configured to hold the substrate W. Specifically, the hand portion 84B is configured to hold the substrate W by supporting the substrate W from thereunder.

The first transfer robot 84 further includes an elevator (which is an elevating structure) (not shown) capable of elevating and lowering the telescopic arm 84A with respect to the moving table 85. The telescopic arm 84A is moved up and down with respect to the moving table 85 by the elevator of the first transfer robot 84.

By extending and retracting the telescopic arm 84A with respect to the container 80, the first transfer robot 84 is configured to be capable of transferring (taking out) the substrate W from the container 80 with the hand portion 84B and capable of transferring (inserting) the substrate W (which is processed) into the container 80.

An operation of the first transfer robot 84 to transfer the substrate W to and from the container 80 placed on the loading port structure 82 and an operation of the first transfer robot 84 to transfer and deliver the substrate W to and from the second transfer robot 60 are controlled by the transfer controller 110. Specifically, in the first transfer robot 84, a movement operation of the moving table 85, an extension and retraction operation of the telescopic arm 84A and an elevating and lowering operation of the telescopic arm 84A are controlled by the transfer controller 110. Further, the controller 100 determines which one of the four containers 80 is to be selected as a destination to and from which the first transfer robot 84 transfers and delivers the substrate W.

In the substrate processing apparatus 20 according to the present embodiments, as shown in FIG. 1, when the placement chamber 78 is arranged in front of a maintenance area M, the first transfer chamber 86 is arranged behind the placement chamber 78 and parallel to the placement chamber 78, the second transfer chamber 50 is arranged behind the first transfer chamber 86 and perpendicular to the first transfer chamber 86, and the process module 30 is arranged behind the first transfer chamber 86 and parallel to the second transfer chamber 50.

### <Controller>

As shown in FIG. 3, the substrate processing apparatus 20 includes the controller 100. The controller 100 is configured as a computer including a CPU (Central Processing Unit) 101A, a RAM (Random Access Memory) 101B, a memory 101C and an I/O (input/output) port 101D.

The RAM 101B, the memory 101C and the I/O port 101D are configured to be capable of exchanging data with the CPU 101A via an internal bus 101E. For example, an input/output device (“I/O DEVICE” shown in FIG. 3) 102 constituted by a component such as a touch panel (not shown) may be connected to the controller 100. Further, the input/output device 102 may serve as an example of a manipulator of the present embodiments. In addition, for example, an external communication interface (“ECI” shown in FIG. 3) 104 configured to communicate with a host apparatus may be connected to the controller 100.

The memory 101C may be embodied by a component such as a flash memory and a hard disk drive (HDD). For example, a control program configured to control operations of the substrate processing apparatus 20 and a process recipe containing information on sequences and conditions of a substrate processing described later may be readably stored in the memory 101C. The process recipe is obtained by combining steps of the substrate processing described later such that the controller 100 can execute the steps to acquire a predetermined result, and functions as a program. Hereinafter, the process recipe and the control program may be collectively or individually referred to as a “program”. Further, the process recipe may also be simply referred to as a “recipe”. Thus, in the present specification, the term “program” may refer to the recipe alone, may refer to the control program alone, or may refer to both of the recipe and the control program. The RAM 101B functions as a memory area (work area) where a program or data read by the CPU 101A is temporarily stored.

The I/O port 101D is connected to components such as the transfer controller (“TC” shown in FIG. 3) 110 and a plurality of process controllers (“1ST PC”, “2ND PC”, . . . , and “nTH PC” shown in FIG. 3) 120. Hereinafter, each of the plurality of process controllers 120 may also be referred to as a “process controller 120”. The transfer controller 110 is configured to be capable of controlling a transfer operation of the substrate W. The process controllers 120 are configured to be capable of controlling the film forming process on the substrate W. According to the present embodiments, for example, since the four process modules 30 are provided, four process controllers 120 are provided corresponding to the four process modules 30, respectively. Thereby, it is possible to perform the film forming process independently for each process module 30.

The CPU 101A is configured to read the control program from the memory 101C and execute the read control program. Furthermore, the CPU 101A is configured to read the recipe from the memory 101C in accordance with an operation command inputted from the input/output device 102. In accordance with the contents of the read recipe, the CPU 101A is configured to be capable of controlling the transfer controller 110 to control various operations such as the transfer operation of the substrate W performed by the first transfer robot (“1ST TR” shown in FIG. 3) 84, the elevator 37 and the second transfer robot (“2ND TR” shown in FIG. 3) 60, opening and closing operations of the gate valve 35 and the shutter and a positioning operation of the loading port structure 82.

In addition, in accordance with the contents of the read recipe, the CPU 101A is configured to be capable of controlling the process controller 120 to control the temperature controller 122, the gas flow rate controller 124 and the pressure controller 126. The temperature controller 122 is configured to be capable of controlling a temperature regulating operation (temperature adjusting operation) of the heater that heats the inside of the reaction furnace 32. The gas flow rate controller 124 is configured to be capable of controlling a flow rate regulating operation (flow rate adjusting operation) of the gas supplied into the reaction furnace 32. The pressure controller 126 is configured to be capable of controlling a pressure regulating operation (pressure adjusting operation) within the reaction furnace 32.

The controller 100 may be embodied by installing the above-described program stored in an external memory 103 into a computer. For example, the external memory 103 may include a magnetic disk such as a hard disk drive (HDD), an optical disk such as a CD, a magneto-optical disk such as an MO, and a semiconductor memory such as a USB memory. The memory 101C or the external memory 103 may be embodied by a non-transitory computer readable recording medium. Hereafter, the memory 101C and the external memory 103 may be collectively or individually referred to as a “recording medium”. Thus, in the present specification, the term “recording medium” may refer to the memory 101C alone, may refer to the external memory 103 alone, or may refer to both of the memory 101C and the external memory 103. Instead of the external memory 103, a communication interface such as the Internet and a dedicated line may be used for providing the program to the computer.

For example, the memory 101C further stores a plurality of pieces of layout information indicating arrangements of the placement chamber 78, the first transfer chamber 86, the second transfer chamber 50 and the process modules 30. Specifically, the plurality of pieces of layout information may include first layout information and second layout information. The first layout information is information indicating that the process modules 30 (the four process modules 30 in the present embodiments) are arranged such that each entrance 34 faces toward a first direction perpendicular to the substrate transfer direction in the second transfer chamber 50 when viewed from above of the substrate processing apparatus 20. The second layout information is information indicating that the process modules 30 are arranged such that each entrance 34 faces toward a second direction (which is different from the first direction) with respect to the substrate transfer direction. In addition, according to the present embodiments, the first direction and the second direction are mutually opposite directions.

For example, the memory 101C further stores a plurality of pieces of transfer operation information of the first transfer robot 84 respectively in association with the plurality of pieces of layout information and a plurality of pieces of transfer operation information of the second transfer robot 60 respectively in association with the plurality of pieces of layout information.

The transfer operation information of the second transfer robot 60 includes information on a delivery direction in which the substrate W is transferred and delivered to and from an inside of the process module 30 via the entrance 34 of the process module 30. Specifically, the transfer operation information of the second transfer robot 60 includes information on a direction of extension and retraction of the telescopic arm 64 (the same direction as the delivery direction) when the substrate W is transferred and delivered.

For example, the transfer operation information of the second transfer robot 60 further includes position information of the process modules 30. Further, the position information of the process modules 30 may be information regarding a distance from a reference position “B” (shown in FIG. 1) of the second transfer robot 60 to a delivery position of the substrate W to each process module 30. For example, according to the present embodiments, the reference position B of the second transfer robot 60 is set to a position closest to the first transfer chamber 86 of the second transfer robot 60 moving on the transfer rail 52. However, the present embodiments are not limited thereto. The second transfer robot 60 transfers the substrate W to the designated process module among the process modules 30 by moving on the transfer rail 52 based on the position information of the process module 30 designated by the controller 100.

The controller 100 is configured to be capable of controlling the operations of the first transfer robot 84 and the second transfer robot 60 based on the layout information stored in the memory 101C. Specifically, the controller 100 includes the transfer controller 110 configured to control the operations of the first transfer robot 84 and the second transfer robot 60, and is configured to be capable of controlling the operations of the first transfer robot 84 and the second transfer robot 60 via the transfer controller 110. More specifically, by acquiring a specific piece of transfer operation information associated with a specific piece of layout information selected from the plurality of pieces of layout information, and passing the specific piece of the transfer operation information acquired as described above to the transfer controller 110, the controller 100 is configured to be capable of controlling the operations of the first transfer robot 84 and the second transfer robot 60.

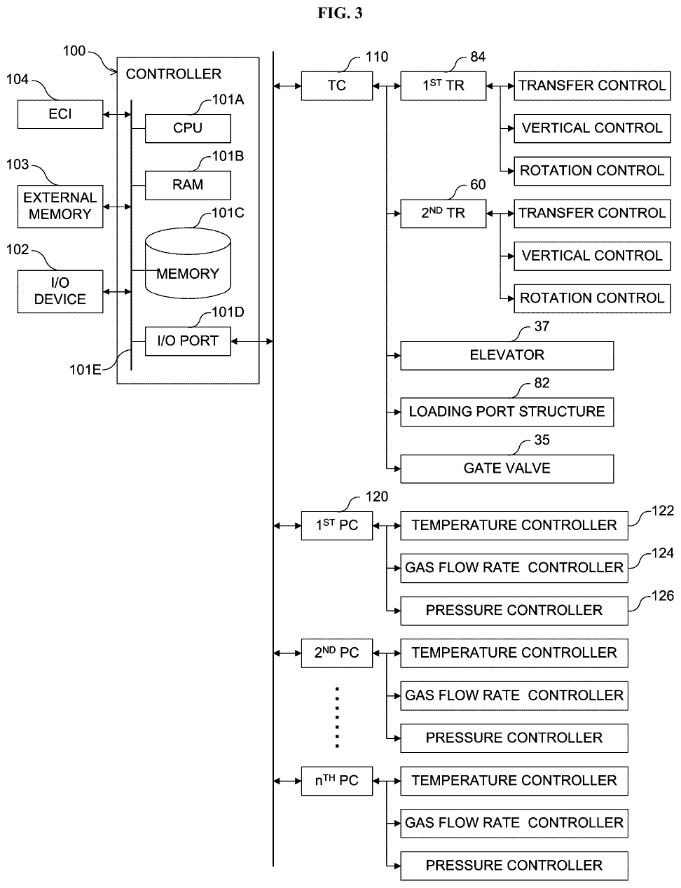

For example, the input/output device 102 is further configured to be capable of setting information for selecting a specific piece of layout information from the plurality of pieces of layout information. Specifically, as shown in FIG. 4, on a system parameter setting screen for setting an apparatus configuration of the substrate processing apparatus 20, the number of the process modules 30 is input (or selected), and an arrangement of the second transfer chamber 50 with respect to the process modules 30 is set. In the present embodiments, the “arrangement of the second transfer chamber 50 with respect to the process modules 30” may refer to a left side arrangement or a right side arrangement when the placement chamber 78 of the substrate processing apparatus 20 is in the front. The controller 100 is configured to select a specific piece of layout information from the plurality of pieces of layout information based on information regarding the number of process modules 30 and the arrangement of the second transfer chamber 50 with respect to the process modules 30, and is further configured to pass the specific piece of the layout information selected as described above to the transfer controller 110.

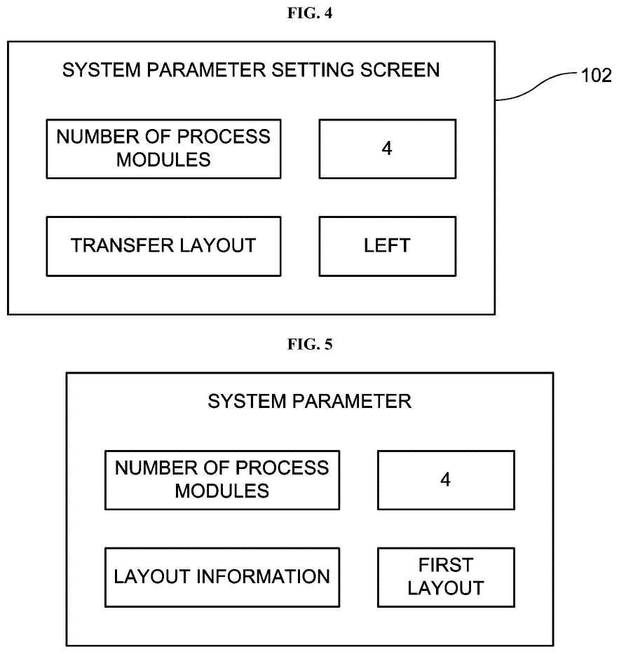

FIG. 5 is a diagram schematically illustrating a specific piece of layout information selected by the controller 100 based on the information input by the input/output device 102. In an example shown in FIG. 5, the first layout information is selected as the specific piece of the layout information.

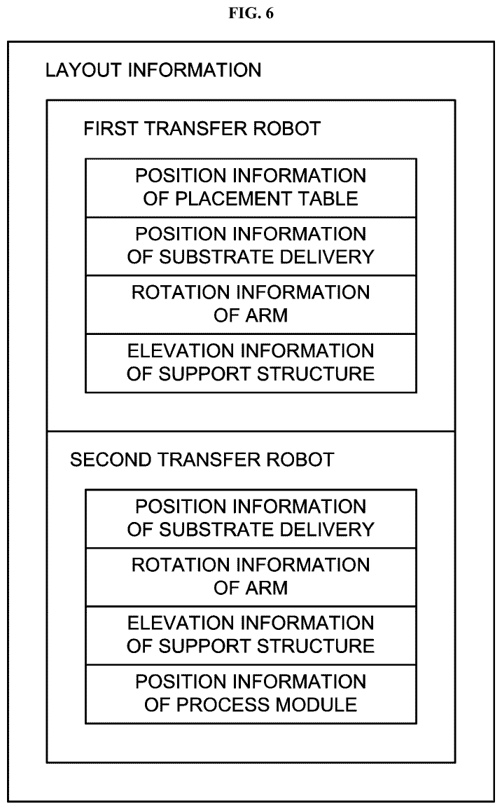

FIG. 6 is a diagram schematically illustrating an example of the transfer operation information of the first transfer robot 84 and the transfer operation information of the second transfer robot 60 associated with the layout information. Position information of a placement table of the first transfer robot 84 is position information of each of the containers 80 placed on each of the loading port structures 82. Position information of a substrate delivery of the first transfer robot 84 is information on the substrate delivery position D at which the substrate W is transferred and delivered to and from the second transfer robot 60. Rotation information of the arm (that is, the telescopic arm 84A) of the first transfer robot 84 is information on the extension and retraction operation of the telescopic arm 84A. Elevation information of a support structure (not shown) of the first transfer robot 84 is information on an elevating and lowering operation of the support structure rotatably supporting the telescopic arm 84A in the horizontal direction. Further, position information of a substrate delivery of the second transfer robot 60 is information on the substrate delivery position D at which the substrate W is transferred and delivered to and from the first transfer robot 84. Rotation information of the arm (that is, the telescopic arm 64) of the second transfer robot 60 is information on the extension and retraction operation of the telescopic arm 64. Elevation information of a support structure (not shown) of the second transfer robot 60 is information on an elevating and lowering operation of the support structure rotatably supporting the telescopic arm 64 in the horizontal direction. Position information of the process module 30 of the second transfer robot 60 is position information of each process module 30.

For example, when the placement chamber 78, the first transfer chamber 86, the second transfer chamber 50 and the process module 30 are electrically connected to the controller 100, the controller 100 becomes capable of selecting a specific piece of layout information from the plurality of pieces of layout information. In other words, when one of the components described above is electrically disconnected, the controller 100 becomes incapable of selecting any piece of layout information. Thereby, it is possible to prevent a startup of the controller 100 during a poor connection.

For example, when the layout information is set in advance and one of the placement chamber 78, the first transfer chamber 86, the second transfer chamber 50 and the process module 30 is electrically disconnected from the controller 100, the controller 100 may determine that there is a mismatch between the layout information set in advance and the apparatus configuration so that the startup of the controller 100 may be prevented.

For example, the controller 100 is further configured to be capable of controlling the transfer controller 110 in accordance with a processing of the substrate W.

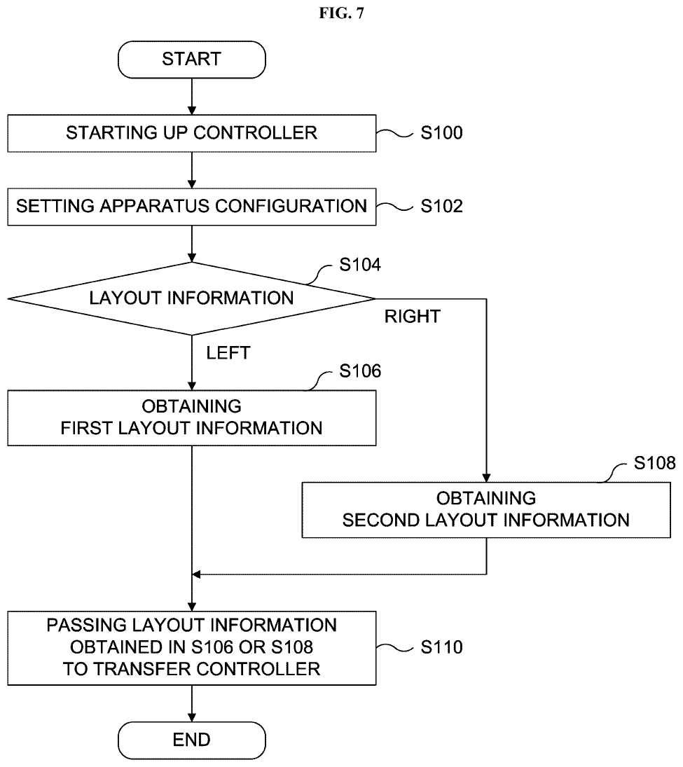

Subsequently, an initial setting operation when the substrate processing apparatus 20 is installed in a site such as a factory will be described. First, the components (the placement chamber 78, the first transfer chamber 86, the second transfer chamber 50 and the process modules 30) constituting the substrate processing apparatus 20 are installed in the factory, and the components are electrically connected to one another. After the components constituting the substrate processing apparatus 20 are electrically connected to one another, the substrate processing apparatus 20 is started up (or activated). When the substrate processing apparatus 20 is started up, the controller 100 is started up as shown in FIG. 7 (step S100). When the controller 100 is started up, the system parameter setting screen shown in FIG. 4 is displayed. An operating personnel sets various parameters while checking the system parameter setting screen (step S102). When various parameters are set by the operating personnel, the controller 100 selects a specific piece of layout information from the plurality of pieces of layout information (step S104). In such a state, when the operating personnel has set a transfer layout to “LEFT”, the controller 100 performs a step S106. On the other hand, the operating personnel has set the transfer layout to “RIGHT”, the controller 100 performs a step S108. In the step S106, the controller 100 selects the first layout information as the specific piece of the layout information. On the other hand, in the step S108, the controller 100 selects the second layout information as the specific piece of the layout information. Then, in a step S110, the specific piece of the layout information selected by the controller 100 is passed to the transfer controller 110. The transfer controller 110 controls the operations of the first transfer robot 84 and the second transfer robot 60 based on the transfer operation information of the first transfer robot 84 and the transfer operation information of the second transfer robot 60 in association with the layout information passed as described above.

### <Method of Manufacturing Semiconductor Device>

Subsequently, a method of manufacturing a semiconductor device using the substrate processing apparatus 20 according to the embodiments of the present disclosure, that is, a procedure of processing the substrate W will be described.

When the substrate processing apparatus 20 is started up, the controller 100 selects a specific piece of layout information based on various parameters which are set as described above, and passes the transfer operation information of the first transfer robot 84 and the transfer operation information of the second transfer robot 60 to the transfer controller 110. The transfer controller 110 controls the operations of the first transfer robot 84 and the second transfer robot 60 based on the transfer operation information of the first transfer robot 84 and the transfer operation information of the second transfer robot 60 passed as described above.

When an order for the substrate processing is input, the transfer controller 110 operates the first transfer robot 84 and the second transfer robot 60 in response to a request from the controller 100. First, the first transfer robot 84 in the first transfer chamber 86 is used to transfer (take out) the substrate W from the container 80 placed in the placement chamber 78.

Then, the first transfer robot 84 is moved to transfer the substrate W to the second transfer robot 60 of the second transfer chamber 50.

Then, the second transfer robot 60 that has received the substrate W moves toward the designated process module 30 and transfers the substrate W to the substrate support 40.

The substrate support stand 40 that has received the substrate W is elevated and loaded into the reaction furnace 32. Then, the film forming process is performed onto the substrate W charged (loaded) into the reaction furnace 32.

In a manner described above, the film forming process on the substrate W is performed. Thereby, the semiconductor device is manufactured.

Hereinafter, actions and effects of the present embodiments will be described. According to the present embodiments, the operations of the first transfer robot 84 and the second transfer robot 60 are controlled based on the plurality of pieces of layout information indicating the arrangements (stored in the memory 101C) of the placement chamber 78, the first transfer chamber 86, the second transfer chamber 50 and the processing modules 30. Thereby, it is possible to reduce a burden on the operating personnel in setting the transfer operation information of the transfer robot (that is, the first transfer robot 84 and the second transfer robot 60) configured to transfer the substrate W. In particular, it is possible to reduce the burden on the operating personnel during the initial setting operation immediately after the substrate processing apparatus 20 is installed in the factory. Further, even when the process module 30 is added to the substrate processing apparatus 20, it is possible to the burden on the operating personnel during the setting operation.

Further, according to the present embodiments, the placement chamber 78 is arranged in front of the maintenance area M and the first transfer chamber 86, the second transfer chamber 50 and the process module 30 are arranged based on the location of the placement chamber 78 as a reference. Thereby, when two substrate processing apparatuses including the substrate processing apparatus 20 are installed in the factory, it is possible to share the maintenance area M between the two substrate processing apparatuses, and it is also possible to reduce an installation space for the two substrate processing apparatuses.

Further, according to the present embodiments, the layout information includes the first layout information and the second layout information. Thereby, it is possible to reduce the burden on the operating personnel in setting the layout in accordance with the apparatus configuration, and it is also possible to prevent an erroneous operation by the operating personnel.

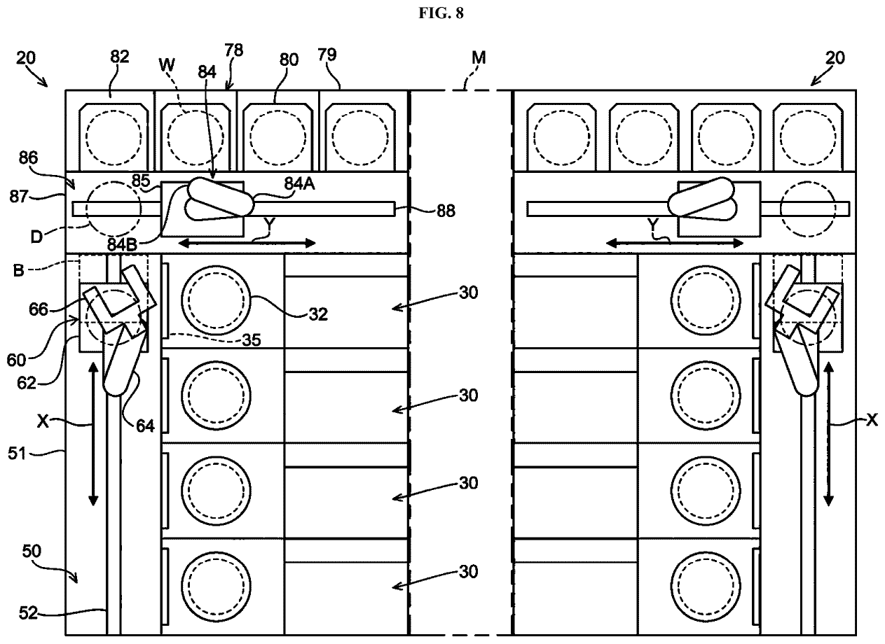

For example, when a plurality of substrate processing apparatuses including the substrate processing apparatus 20 are installed side by side in a semiconductor factory, the maintenance area M for performing a maintenance operation is provided on each substrate processing apparatus. Hereinafter, the plurality of substrate processing apparatuses including the substrate processing apparatus 20 may also be referred to as “substrate processing apparatuses 20”. However, as shown in FIG. 8, by changing an apparatus layout, it is possible to share the maintenance area M between the substrate processing apparatuses 20. As a result, it is possible to reduce an apparatus installation area, and it is also possible to secure the number of the substrate processing apparatuses 20 to be installed. For example, in FIG. 8, the substrate processing apparatuses (two substrate processing apparatuses in FIG. 8) 20 are arranged so as to share the maintenance area M with each other. Specifically, the maintenance area M is provided for the substrate processing apparatuses 20 at a location opposite to the second transfer chamber 50 with the process modules 30 therebetween. As shown in FIG. 8, a substrate processing system according to the present embodiments includes the substrate processing apparatuses 20 arranged so as to share the maintenance area M with each other.

Further, according to the present embodiments, the memory 101C stores the plurality of pieces of transfer operation information of the first transfer robot 84 respectively in association with each of the plurality of pieces of layout information and the plurality of pieces of transfer operation information of the second transfer robot 60 respectively in association with the plurality of pieces of layout information. Thereby, when the layout information is determined, the transfer operation information of the first transfer robot 84 and the transfer operation information of the second transfer robot 60 are automatically developed so as to control the operations of the first transfer robot 84 and the second transfer robot 60.

Further, according to the present embodiments, by inputting various parameters on the system parameter setting screen from the input/output device 102, the controller 100 selects and develops a specific piece of layout information from the plurality of pieces of layout information. Therefore, as compared with a case where the operating personnel manually sets the transfer operation information of the first transfer robot 84 and the transfer operation information of the second transfer robot 60 in accordance with the apparatus configuration, it is possible to reduce the burden on the operating personnel.

Further, according to the present embodiments, when a specific piece of layout information is selected by the controller 100, the specific piece of the layout information selected by the controller 100 is passed to the transfer controller 110. Therefore, it is possible to reduce the burden on the operating personnel, and it is also possible to shorten a setup operation time.

Further, according to the present embodiments, the transfer operation information of the second transfer robot 60 includes the information on the delivery direction in which the substrate W is transferred and delivered to and from the inside of the process module 30 via the entrance 34. Therefore, it is possible to reduce a work time for the operating personnel to perform the setting each time in accordance with the apparatus layout.

Further, according to the present embodiments, the transfer operation information of the second transfer robot 60 includes the position information of the process modules 30. Therefore, it is possible to easily obtain the distance between the second transfer robot 60 and the target process module among the process modules 30.

Further, according to the present embodiments, the second transfer robot 60 moves along the transfer rail 52 based on the position information of the process modules 30. Therefore, it is possible for the second transfer robot 60 to move to a desired process module (the target process module) accurately and quickly.

Further, according to the present embodiments, the arm (that is, the telescopic arm 64) of the second transfer robot 60 transfers and delivers the substrate W to and from the process module 30. A movement of the telescopic arm 64 is also included in the transfer operation information of the second transfer robot 60. Therefore, it is possible to reduce the work time for the operating personnel to perform the setting each time in accordance with the apparatus layout. Further, it is also possible to prevent an erroneous setting by the operating personnel.

Further, according to the present embodiments, the telescopic arm 84A of the first transfer robot 84 transfers the substrate W to and from the container 80. A movement of the telescopic arm 84A is also included in the transfer operation information of the first transfer robot 84. Therefore, it is possible to reduce the work time for the operating personnel to perform the setting each time in accordance with the apparatus layout. Further, it is also possible to prevent an erroneous setting by the operating personnel.

Further, according to the present embodiments, by directly transferring and delivering the substrate W between the first transfer robot 84 and the second transfer robot 60, it is possible to omit an area where the substrate W is temporarily placed, and it is also possible to simplify the apparatus configuration.

Further, according to the present embodiments, when the placement chamber 78, the first transfer chamber 86, the second transfer chamber 50 and the process module 30 are connected to the controller 100, it is possible to select a piece of layout information from the plurality of pieces of layout information. Therefore, it is possible to reliably develop the transfer operation information.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process sequences and the process conditions of each process using the substrate processing apparatuses exemplified above may be substantially the same as those of the embodiments mentioned above. Even in such a case, it is possible to obtain substantially the same effects as in the embodiments mentioned above.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof. For example, the embodiments mentioned above are described by way of an example in which the substrate W is transferred by the first transfer robot 84 and the second transfer robot 60. However, the technique of the present disclosure is not limited thereto. For example, the first transfer robot 84 and the second transfer robot 60 may be configured to move the substrate W from the container 80 to a sealed container and to transfer the sealed container, or may be configured to transfer the container 80. Even in such a case, it is possible to obtain substantially the same effects as those of the embodiments mentioned above. In addition, in such a case, it is possible to simultaneously transfer the plurality of substrates W to the process module 30 by the second transfer robot 60. Thereby, it is possible to shorten a transfer time of the substrates W.

For example, the embodiments and the modified examples described above may be appropriately combined. The process sequences and the process conditions of each combination thereof may be substantially the same as those of the embodiments or the modified examples described above.

According to some embodiments of the present disclosure, it is possible to reduce the burden on the operating personnel in setting the transfer operation information of the transfer robot configured to transfer the substrate.

What is claimed is:

1. A substrate processing apparatus comprising:
a placement chamber in which a container accommodating a substrate is placed;
a first transfer chamber provided with a first transfer robot therein, wherein the first transfer robot is configured to transfer the substrate to and from the container;
a plurality of process modules configured to process the substrate;
a second transfer chamber provided with a second transfer robot therein and configured to transfer and deliver the substrate between the first transfer chamber and each of the plurality of process modules;
a memory configured to store a plurality of pieces of layout information indicating arrangements of the placement chamber, the first transfer chamber, the second transfer chamber and the plurality of process modules; and
a controller configured to be capable of controlling operations of the first transfer robot and the second transfer robot based on at least one of the plurality of pieces of layout information in the memory,
wherein the plurality of pieces of layout information are different from each other in the arrangements of at least one of the placement chamber, the first transfer chamber, the second transfer chamber and the plurality of the process modules.

2. The substrate processing apparatus of claim 1, wherein, when the placement chamber is arranged in front of a maintenance area, the first transfer chamber is arranged behind the placement chamber and parallel to the placement chamber, the second transfer chamber is arranged behind the first transfer chamber and perpendicular to the first transfer chamber, and each of the plurality of process modules is arranged behind the first transfer chamber and parallel to the second transfer chamber.

3. The substrate processing apparatus of claim 1, wherein each of the plurality of process modules is provided with an entrance for the substrate, and
the plurality of pieces of layout information comprises:
first layout information indicating that the plurality of process modules are arranged such that each entrance thereof faces toward a first direction perpendicular to a substrate transfer direction in the second transfer chamber when viewed from above; and
second layout information indicating that the plurality of process modules are arranged such that each entrance thereof faces toward a second direction different from the first direction with respect to the substrate transfer direction when viewed from above.

4. The substrate processing apparatus of claim 3, wherein the first direction and the second direction are mutually opposite directions.

5. The substrate processing apparatus of claim 1, wherein the memory is further configured to store a plurality of pieces of transfer operation information of the first transfer robot respectively in association with the plurality of pieces of layout information and a plurality of pieces of transfer operation information of the second transfer robot respectively in association with the plurality of pieces of layout information.

6. The substrate processing apparatus of claim 5, further comprising
a manipulator configured to be capable of setting information for selecting a specific piece of layout information from the plurality of pieces of layout information.

7. The substrate processing apparatus of claim 6, further comprising
a transfer controller configured to control the operations of the first transfer robot and the second transfer robot,
wherein the controller is further configured to be capable of controlling the operations of the first transfer robot and the second transfer robot by acquiring a first piece of transfer operation information of the first transfer robot associated with the specific piece of the layout information from the plurality of pieces of transfer operation information of the first transfer robot and a second piece of transfer operation information of the second transfer robot associated with the specific piece of the layout information from the plurality of pieces of transfer operation information of the second transfer robot, and passing the first piece of the transfer operation information of the first transfer robot and the second piece of the transfer operation information of the second transfer robot to the transfer controller.

8. The substrate processing apparatus of claim 5, wherein each of the plurality of process modules is provided with an entrance for the substrate, and
the plurality of pieces of transfer operation information of the second transfer robot comprise information on a delivery direction in which the substrate is transferred and delivered to and from an inside of each of the plurality of process modules via the entrance thereof.

9. The substrate processing apparatus of claim 5, wherein the plurality of pieces of transfer operation information of the second transfer robot comprise position information of the plurality of process modules.

10. The substrate processing apparatus of claim 9, wherein the second transfer chamber is provided with a transfer rail, and
the second transfer robot is configured to transfer the substrate by moving toward a designated process module among the plurality of process modules along the transfer rail based on the position information.

11. The substrate processing apparatus of claim 1, wherein the second transfer robot is provided with an arm configured to be rotatable in a horizontal direction and configured to be extendable and retractable, and
wherein the arm is further configured to transfer and deliver the substrate to and from each of the plurality of process modules.

12. The substrate processing apparatus of claim 1, wherein the first transfer robot is provided with an arm configured to be rotatable in a horizontal direction and configured to be extendable and retractable, and
wherein the arm is further configured to transfer and deliver the substrate to and from the container.

13. The substrate processing apparatus of claim 1, wherein the first transfer robot and the second transfer robot are configured to directly transfer and deliver the substrate to and from each other.

14. The substrate processing apparatus of claim 1, wherein the controller is configured to be capable of selecting a piece of the layout information from the plurality of pieces of layout information when the placement chamber, the first transfer chamber, the second transfer chamber and the plurality of process modules are connected to the controller.

15. A substrate processing system comprising
a plurality of substrate processing apparatuses configured as the substrate processing apparatus of claim 1,
wherein the plurality of substrate processing apparatuses are arranged such that a maintenance area thereof is shared therebetween.

16. The substrate processing system of claim 15, wherein the maintenance area is provided at a location opposite to a second transfer chamber of each of the plurality of process modules.

17. A method of manufacturing a semiconductor device, comprising:
(a) storing a plurality of pieces of layout information indicating arrangements of a placement chamber in which a container accommodating a substrate is placed, a first transfer chamber, a second transfer chamber and a plurality of process modules configured to process the substrate, wherein the placement chamber, the first transfer chamber, the second transfer chamber and the plurality of process modules are arranged such that an operation of transferring the substrate from the placement chamber to a first transfer robot of the first transfer chamber, an operation of transferring the substrate to a second transfer robot of the second transfer chamber and an operation of transferring the substrate received by the second transfer robot to a process module among the plurality of process modules are capable of being performed;
(b) controlling operations of the first transfer robot and the second transfer robot based on at least one of the plurality of pieces of layout information; and
(c) processing the substrate in the process module,
wherein the plurality of pieces of layout information are different from each other in the arrangements of at least one of the placement chamber, the first transfer chamber, the second transfer chamber and the plurality of the process modules.

18. A non-transitory computer-readable recording medium storing a program that causes, by a computer, a substrate processing apparatus to perform:
(a) storing a plurality of pieces of layout information indicating arrangements of a placement chamber in which a container accommodating a substrate is placed, a first transfer chamber, a second transfer chamber and a plurality of process modules configured to process the substrate, wherein the placement chamber, the first transfer chamber, the second transfer chamber and the plurality of process modules are arranged such that an operation of transferring the substrate from the placement chamber to a first transfer robot of the first transfer chamber, an operation of transferring the substrate to a second transfer robot of the second transfer chamber and an operation of transferring the substrate received by the second transfer robot to a process module among the plurality of process modules are capable of being performed;
(b) controlling operations of the first transfer robot and the second transfer robot based on at least one of the plurality of pieces of layout information; and
(c) processing the substrate in the process module,
wherein the plurality of pieces of layout information are different from each other in the arrangements of at least one of the placement chamber, the first transfer chamber, the second transfer chamber and the plurality of the process modules.
